(19) United States
(12) Patent Application Publication
(10) Pub. No.: US 2018/0277343 A1
(43) Pub. Date: Sep. 27, 2018

(54) APPARATUS CONFIGURED FOR SPUTTER DEPOSITION ON A SUBSTRATE, SYSTEM CONFIGURED FOR SPUTTER DEPOSITION ON A SUBSTRATE, AND METHOD FOR SPUTTER DEPOSITION ON A SUBSTRATE

(71) Applicant: Applied Materials, Inc., Santa Clara, CA (US)

(72) Inventor: John M. WHITE, Hayward, CA (US)

(21) Appl. No.: 15/761,028

(22) PCT Filed: Apr. 28, 2016
(86) PCT No.: PCT/US2016/029740

§ 371 Date: Mar. 16, 2018

Related U.S. Application Data
(60) Provisional application No. 62/252,900, filed on Nov. 9, 2015.
(60) Provisional application No. 62/246,401, filed on Oct. 26, 2015.
(60) Provisional application No. 62/246,095, filed on Oct. 25, 2015.

(51) Int. Cl. H01J 37/34; C23C 14/35

(52) U.S. Cl. CPC H01J 37/3452; C23C 14/35; H01J 37/3405; H01J 37/3417; H01J 37/3423

(57) ABSTRACT

The present disclosure provides an apparatus configured for sputter deposition on a substrate. The apparatus includes a cylindrical sputter cathode rotatable around a rotational axis, and a magnet assembly configured to provide a first plasma racetrack and a second plasma racetrack on opposite sides of the cylindrical sputter cathode, wherein the magnet assembly includes two, three or four magnets each having two poles and one or more sub-magnets, wherein the two, three or four magnets are configured for generating both the first plasma racetrack and the second plasma racetrack.

### FIELD

Embodiments of the present disclosure relate to an apparatus configured for sputter deposition on a substrate, a system configured for sputter deposition on a substrate, and a method for sputter deposition on a substrate. Embodiments of the present disclosure particularly relate to a bi-directional sputter deposition source and a dynamic sputter deposition system.

### BACKGROUND

Techniques for layer deposition on a substrate include, for example, sputter deposition, thermal evaporation, and chemical vapor deposition. A sputter deposition process can be used to deposit a material layer on the substrate, such as a layer of a conducting material or an insulating material. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxynitride of the target material on the substrate.

Coated materials may be used in several applications and in several technical fields. For instance, an application lies in the field of microelectronics, such as generating semiconductor devices. Also, substrates for displays are often coated by a sputter deposition process. Further applications include insulating panels, substrates with TFT, color filters or the like.

As an example, in display manufacturing, it is beneficial to reduce the manufacturing costs of displays, e.g., for mobile phones, tablet computers, television screens, and the like. A reduction in manufacturing costs can be achieved, for example, by increasing a throughput of a processing system, such as a sputter deposition system, or by reducing a number of targets to reduce the system capital cost. Further, a space available for a sputter processing system can be limited. Moreover, a layer uniformity of the material layers deposited on the substrate is beneficial.

In view of the above, apparatuses, systems and methods for sputter deposition on a substrate that overcome at least some of the problems in the art are beneficial. The present disclosure particularly aims at providing apparatuses, systems and methods that provide for at least one of an increased throughput, fewer targets, reduced installation space for a sputter deposition system, and/or an improved layer uniformity.

### SUMMARY

In light of the above, an apparatus configured for sputter deposition on a substrate, a system configured for sputter deposition on a substrate, and a method for sputter deposition on a substrate are provided. Further aspects, benefits, and features of the present disclosure are apparent from the claims, the description, and the accompanying drawings.

According to an aspect of the present disclosure, an apparatus configured for sputter deposition on a substrate is provided. The apparatus includes a cylindrical sputter cathode rotatable around a rotational axis, and a magnet assembly within the cylindrical sputter cathode and configured to provide a first plasma racetrack and a second plasma racetrack on opposite sides of the cylindrical sputter cathode, wherein the magnet assembly includes two, three or four magnets each having two poles and one or more sub-magnets, wherein the two, three or four magnets are configured for generating both the first plasma racetrack and the second plasma racetrack.

According to a further aspect of the present disclosure, an apparatus configured for sputter deposition on a substrate is provided. The apparatus includes a cylindrical sputter cathode rotatable around a rotational axis, and a magnet assembly within the cylindrical sputter cathode and configured to provide a first plasma racetrack and a second plasma racetrack on opposite sides of the cylindrical sputter cathode, wherein the magnet assembly includes a first magnet having one or more first sub-magnets and a pair of second magnets each having one or more second sub-magnets, and wherein the first magnet and the pair of second magnets are configured for generating both the first plasma racetrack and the second plasma racetrack.

According to another aspect of the present disclosure, a system configured for sputter deposition on a substrate is provided. The system includes a vacuum chamber and one or more apparatuses according to the embodiments described herein in the vacuum chamber.

According to a further aspect of the present disclosure, a method for sputter deposition on a substrate is provided. The method includes a generating of a first plasma racetrack and a second plasma racetrack using a magnet assembly in the cylindrical sputter cathode having two, three or four magnets, wherein the two, three or four magnets are configured for generating both the first plasma racetrack and the second plasma racetrack.

According to a yet further aspect of the present disclosure, a method for sputter deposition on a substrate is provided. The method includes a generating of a first plasma racetrack and a second plasma racetrack on opposite sides of a cylindrical sputter cathode using a magnet assembly in the cylindrical sputter cathode having a first magnet including one or more first sub-magnets and a pair of second magnets each including one or more second sub-magnets, and wherein the first magnet and the pair of second magnets are configured for generating both the first plasma racetrack and the second plasma racetrack.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to, embodiments. The accompanying drawings relate to embodiments of the disclosure and are described in the following:

FIG. 1A shows a schematic top view of an apparatus configured for sputter deposition on a substrate according to embodiments described herein;

FIG. 1B shows a schematic view of a magnet assembly of the apparatus of FIG. 1A;

FIGS. 2A-2C show schematic views of magnet assemblies according to further embodiments described herein;

FIG. 3A shows a cross-sectional side view of the apparatus of FIG. 1A;

FIG. 3B shows a schematic side view of the apparatus configured for sputter deposition on a substrate having a plasma racetrack on a side thereof;

FIG. 3C shows a cross-sectional side view of an apparatus configured for sputter deposition on a substrate according to further embodiments described herein;

FIG. 3D shows a cross-sectional side view of an apparatus configured for sputter deposition on a substrate according to yet further embodiments described herein;

FIG. 3E shows a cross-sectional side view of an apparatus configured for sputter deposition on a substrate according to embodiments described herein;

FIGS. 4A-4C show schematic side cross-sectional views of the apparatus configured for sputter deposition on a substrate;

FIG. 5 shows a schematic top view of a bi-directional sputter deposition source used for a simultaneous processing of two substrates according to embodiments described herein;

FIG. 6 shows a schematic horizontal cross-sectional view of a system configured for sputter deposition on a substrate according to embodiments described herein; and

FIG. 7 shows a flow chart of a method for sputter deposition on a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The present disclosure provides a cylindrical sputter cathode having one single integrated magnetron configured to generate magnetic fields on two opposing sides of a target surface. Specifically, the same individual magnets create the same field on the opposing sides of the target surface. This overcomes the disadvantages of having two independent plasma racetracks on the same target surface provided by two independent magnetrons. Specifically, it is challenging to make the two fields have exactly the same strength. The stronger field will have a higher sputter rate, causing side to side, i.e., substrate to substrate, thickness non-uniformity. The embodiments of the present disclosure can provide for substantially the same sputter rate on both sides of the cylindrical sputter cathode.

Further, the integrated magnet assembly for sputtering both sides of a cylindrical target simultaneously can reduce or even prevent a bending of the cylindrical target due to a temperature gradient in the cylindrical target. A thickness uniformity of the layers deposited on the substrates can be improved. The bi-directional sputter deposition source can be used to simultaneously coat two substrates provided at opposing sides of the sputter deposition source. A throughput of a processing system, such as a sputter deposition system, can be increased. Moreover, the bi-directional sputter deposition source uses less installation space within the vacuum chamber and within the factory when compared to, for example, two separate sputter deposition sources used to simultaneously process two substrates.

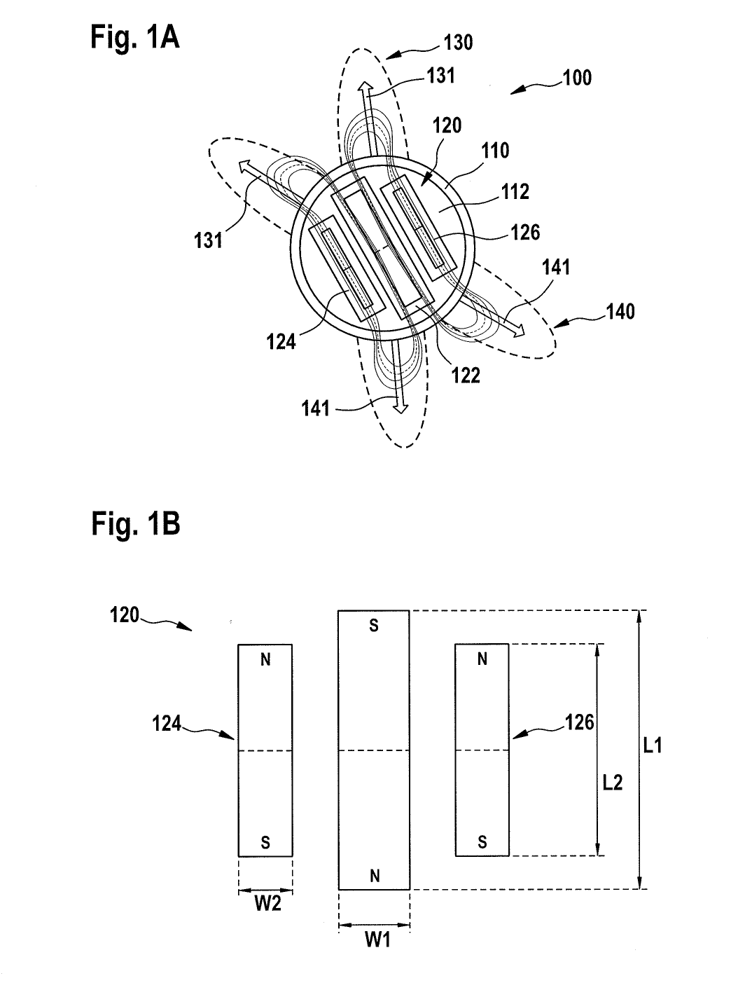

FIG. 1A shows a schematic top view of an apparatus 100 configured for sputter deposition on a substrate according to embodiments described herein. The apparatus 100 can be referred to as “sputter deposition source” or “bi-directional sputter deposition source”.

The apparatus 100 includes a cylindrical sputter cathode 110 rotatable around a rotational axis, and a magnet assembly 120 configured to provide a first plasma racetrack 130 and a second plasma racetrack 140, particularly on opposite sides of the cylindrical sputter cathode 110. The magnet assembly 120 includes two, three or four magnets. In the example of FIG. 1A, the magnet assembly 120 includes three magnets, e.g., a first magnet 122 and a pair of second magnets. The first magnet 122 includes, or consists of, one or more first sub-magnets. Each second magnet includes, or consists of, one or more second sub-magnets. In some implementations, the first magnet 122 can be a first magnet set, and each of the second magnets can be a second magnet set. In particular, each of the first magnet 122 and the pair of second magnets can be respective magnet assemblies of many individual magnets, which can be closely packed together to create what appears, from the magnetic field that is formed, to be one magnet. The first magnet 122 and the pair of second magnets are configured for generating both the first plasma racetrack 130 outside the cylindrical sputter cathode 110 and the second plasma racetrack 140 outside the cylindrical sputter cathode 110. In other words, each magnet of the first magnet 122 and the pair of second magnets participates in the generation of both plasma racetracks. In some implementations, the magnet assembly 120 is configured to provide the first plasma racetrack 130 and the second plasma racetrack 140 substantially symmetrical with respect to the rotational axis.

The three magnets, e.g., each having two magnetic poles, and including the first magnet 122 and the pair of second magnets each generate substantially identical magnetic fields on both sides of the cylindrical sputter cathode 110. A sputter performance on both sides of the cylindrical sputter cathode 110 can be made essentially the same. In particular, a sputter rate on both sides can be substantially identical, such that characteristics, e.g., a layer thickness, on two simultaneously coated substrates can be substantially the same.

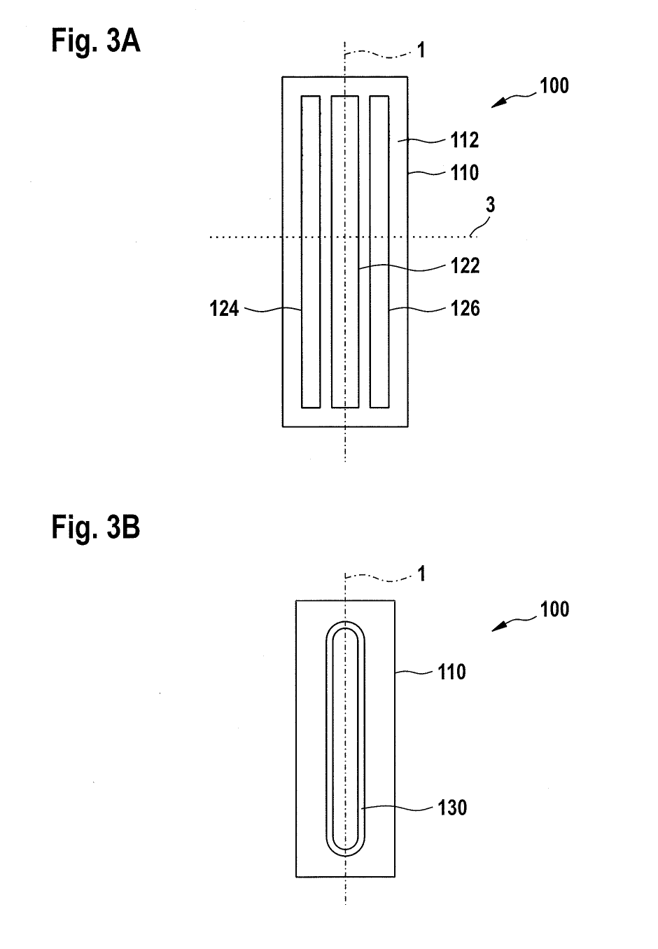

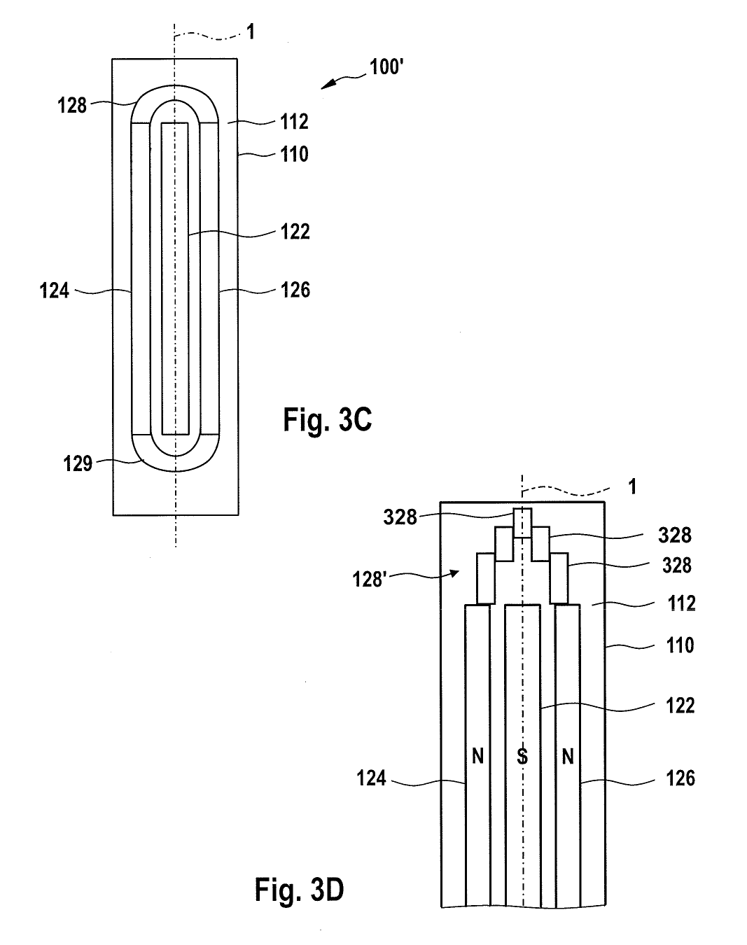

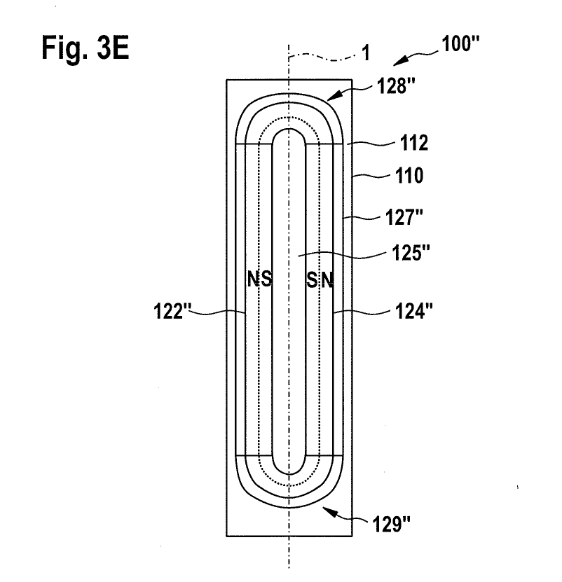

According to the present disclosure, the number of magnets, i.e., the two, three or four magnets of the magnet assembly, can be defined using a cross-sectional plane of the magnet assembly perpendicular to the rotational axis. Specifically, the plane can be provided at a center portion of the magnet assembly and/or the cylindrical sputter cathode along the rotational axis. As an example, the center portion can be provided between a first end (e.g., a top) and a second end (e.g., a bottom) of the magnet assembly. Referring to FIG. 3A, the plane is indicated with reference numeral “2”. In the example of FIG. 1A, although the pair of second magnets, such as a first magnet unit 124 and a second magnet unit 126, can be connected at end portions thereof using one or more magnet connection devices as described with respect to FIG. 3C, the number of magnets is three.

The cylindrical sputter cathode 110 includes a cylindrical target and optionally a backing tube. The cylindrical target can be provided on the backing tube, which can be a cylindrical, metallic tube. The cylindrical target provides the material to be deposited on the substrates. Within the cylindrical sputter cathode 110, a space 112 for a cooling medium, for example, circulating water, can be provided.

The cylindrical sputter cathode 110 is rotatable around a rotational axis. The rotational axis can be a cylinder axis of the cylindrical sputter cathode 110. The term “cylinder” can be understood as having a circular bottom shape and a circular upper shape and a curved surface area or shell connecting the upper circle and the small lower circle. A single magnet set including the first magnet 122 and the pair of second magnets is configured for producing the magnetic fields on both (e.g., opposite) sides of the cylindrical sputter cathode, for example, both sides of the curved surface area or shell to generate the plasma racetracks.

The cylindrical sputter cathode 110 having the magnet assembly 120 can provide for magnetron sputtering for deposition of layers. As used herein, “magnetron sputtering” refers to sputtering performed using a magnetron, i.e. the magnet assembly 120, that is, a unit capable of generating a magnetic field. The magnet assembly 120 is arranged such that the free electrons are trapped within the generated magnetic field. The magnetic field provides the plasma racetracks on the target surface. The term “plasma racetrack” as used throughout the present disclosure can be understood in the sense of electron traps or magnetic-field electron traps provided at or near the target surface. In particular, magnetic field lines penetrating the cylindrical sputter cathode 110 lead to a confinement of electrons in front of the target surface so that due to the high concentration of electrons, a large number of ions and therefore a plasma is produced. The plasma racetracks can also be referred to as “plasma zones”.

The plasma racetracks of the present disclosure should be distinguished from racetrack grooves, which can occur when using planar magnetrons. The presence of a racetrack groove limits a target consumption. When using a rotating cylindrical target, due to the motion, no racetrack groove corresponding to the magnet configuration is formed in the rotating target surface. As a result, a high target material utilization can be achieved.

During sputtering, the cylindrical sputter cathode 110 with the target is rotated around the magnet assembly 120 including the first magnet 122 and the pair of second magnets, such as the first magnet unit 124 and the second magnet unit 126. Specifically, the first magnet unit 124 and the second magnet unit 126 form the pair of second magnets. Each of the first magnet unit 124 and the second magnet unit 126 can include, or consist of, one or more of the second sub-magnets. The first plasma racetrack 130 and the second plasma racetrack 140 can be essentially stationary with respect to the magnet assembly 120. The first plasma racetrack 130 and the second plasma racetrack 140 sweep over the surface of the target while the cylindrical sputter cathode 110 rotates. The cylindrical sputter cathode 110 and the target rotate below and/or past the plasma racetracks.

According to some embodiments, which can be combined with other embodiments described herein, the apparatus 100 provides for the first plasma racetrack 130 and the second plasma racetrack 140, wherein the second plasma racetrack 140 is essentially on the opposite side of the cylindrical sputter cathode 110. In particular, the first plasma racetrack 130 and the second plasma racetrack 140 are symmetrically provided on two opposing sides of the cylindrical sputter cathode 110.

A plasma racetrack, such as each of the first plasma racetrack 130 and/or the second plasma racetrack 140, can each form one single contiguous plasma zone. Even though FIG. 1A shows two portions of each of the first plasma racetrack 130 and the second plasma racetracks 140, the two portions of the respective racetrack are connected by curved portions at the end of the racetrack to form a single plasma zone or a single plasma racetrack (see, e.g., FIG. 3). Accordingly, FIG. 1A shows two plasma racetracks.

Both plasma racetracks are formed by one magnet assembly 120 having the first magnet 122 and a pair of second magnets. Accordingly the first magnet 122 is involved in the generation of the first plasma racetrack 130 and the second plasma racetrack 140. Similarly, the pair of second magnets is also involved in generating the first plasma racetrack 130 and the second plasma racetrack 140. The first magnet 122 and the magnet units of the pair of second magnets can be next to each other, such that the first magnet 122 is between the pair of second magnets.

According to some embodiments described herein, which can be combined with other embodiments described herein, the first magnet 122 has a first magnetic pole in the direction of the first plasma racetrack 130 and a second magnetic pole in the direction of the second plasma racetrack 140. The first magnetic pole can be a magnetic south pole and the second magnetic pole can be a magnetic north pole. In other embodiments, the first magnetic pole can be a magnetic north pole and the second magnetic pole can be a magnetic south pole. The pair of second magnets can have the second magnetic poles (e.g., south poles or north poles) in the direction of the first plasma racetrack 130 and the first magnetic poles (e.g., north poles or south poles) in the direction of the second plasma racetrack 140.

Accordingly, three magnets, each of which may consist of one or more sub-magnets, form two magnetrons, one magnetron forming the first plasma racetrack 130 and one magnetron forming the second plasma racetrack 140. Sharing magnets for the two plasma racetracks reduces potentially occurring differences in the first plasma racetrack 130 and the second plasma racetrack 140, which can occur if the two magnetrons were to be formed by two independent magnetic loops. The arrows 131 show the main direction of material emission from the target upon bombardment of the ions of the plasma in the first plasma racetrack 130. The arrows 141 show the main direction of material emission from the target upon bombardment of the ions of the plasma in the second plasma racetrack 140.

According to some embodiments, which can be combined with other embodiments described herein, the magnet assembly 120 is stationary in the cylindrical sputter cathode 110. The stationary magnet assembly defines stationary plasma racetracks, such as the first plasma racetrack 130 and the second plasma racetrack 140. The stationary plasma racetracks can face respective substrates. The term “stationary plasma racetrack” is to be understood in the sense that the plasma racetrack does not rotate together with the cylindrical sputter cathode 110 around the rotational axis. In particular, the plasma racetrack does not move with respect to the magnet assembly 120. Further, the target is rotated below and/or past the two plasma racetracks.

FIG. 1B shows a schematic view of a magnet assembly 120 of the apparatus 100 of FIG. 1A. The two three or four magnets, such as the first magnet 122 and/or the pair of second magnets, can be permanent magnets. Further, the first magnet 122 and/or the pair of second magnets may consist of one or more sub-magnets.

The pair of second magnets includes two or more second magnets, such as the first magnet unit 124 and the second magnet unit 126. The first magnet 122 can be provided between the first magnet unit 124 and the second magnet unit 126. In particular, the first magnet unit 124 and the second magnet unit 126 can be provided on opposite sides of the first magnet 122. The pair of second magnets can be arranged symmetrically around the first magnet 122.

According to some embodiments, which can be combined with other embodiments described herein, each second magnet, such as the first magnet unit 124 and the second magnet unit 126, of the pair of second magnets includes a first magnetic pole and a second magnetic pole opposite the first magnetic pole. The first magnetic poles of the pair of second magnets are oriented towards the first plasma racetrack and the second magnetic poles of the pair of second magnets are oriented towards the second plasma racetrack, or vice versa. As an example, the first magnetic poles can be magnetic north poles and the second magnetic poles can be magnetic south poles. In other examples, the first magnetic poles can be magnetic south poles and the second magnetic poles can be magnetic north poles.

According to some embodiments, which can be combined with other embodiments described herein, the first magnet 122 includes a first magnetic pole and a second magnetic pole opposite the first magnetic pole, wherein the first magnetic pole of the first magnet is oriented towards the second plasma racetrack and the second magnetic pole of the first magnet is oriented towards the first plasma racetrack, or vice versa. As an example, the first magnetic pole can be a magnetic north pole and the second magnetic pole can be a magnetic south pole. In other examples, the first magnetic pole can be a magnetic south pole and the second magnetic pole can be a magnetic north pole.

The first magnet 122 has a first width W1 and a first length L1. The first length L1 can be measured in a first direction extending from the first magnetic pole to the second magnetic pole of the first magnet 122. The first width W1 can be measured in a second direction perpendicular to the first direction. Each second magnet of the pair of second magnets, such as the first magnet unit 124 and the second magnet unit 126, has a second width W2 and a second length L2. The second length L2 can be measured in the first direction extending from the first magnetic pole to the second magnetic pole of the pair of second magnets. The second width W2 can be measured in a second direction perpendicular to the first direction. The first length L1, the second length L2, the first width W1 and the second width W2 can be defined substantially perpendicular to the rotational axis of the cylindrical sputter cathode.

According to some embodiments, the second length L2 is smaller than the first length L1. As an example, the second length L2 can be less than 90%, specifically less than 80%, and more specifically less than 70% of the first length L1. Additionally or alternatively, the second width W2 is smaller than the first width W1. As an example, the second width W2 can be less than 90%, specifically less than 80%, and more specifically less than 70% of the first width W1. According to embodiments described herein, the first length L1 and the second length L2 are larger than the inner radius of the cylindrical sputter cathode 110.

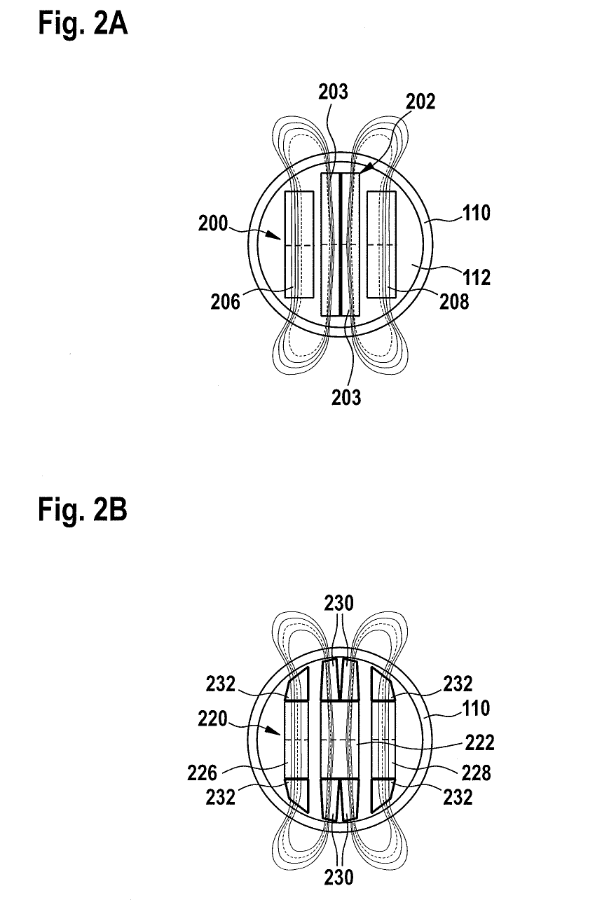

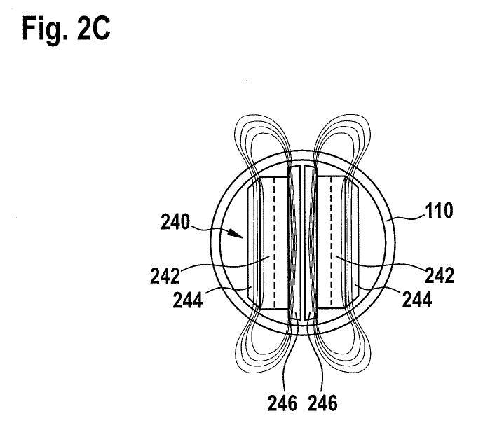

Although FIG. 1B shows a specific magnet configuration having three magnets, which may have the exemplary lengths and widths relations, it is to be understood that the present disclosure is not limited thereto. Other possible magnet configurations with two, three and four magnets are illustrated in FIGS. 2A-C.

FIGS. 2A-C shows schematic views of magnet assemblies according to further embodiments described herein. The magnet configurations of FIGS. 2A-C can give substantially the same magnetic field result on both sides of the cathode because there are only two magnetic loops and each magnetic loop appears on both sides of the cathode. The magnetic flux lines are schematically shown in the FIGs.

FIG. 2A shows a magnet assembly 240 including, or consisting of, four magnets each having two poles and one or more sub-magnets, wherein the four magnets are configured for generating both the first plasma racetrack and the second plasma racetrack. The two poles of each magnet are shown on the upper and lower side, respectively, of the dashed line. The magnet assembly 200 has a pair of first magnets 202 and a pair of second magnets. The pair of second magnets has a first magnet unit 206 and a second magnet unit 208 provided on opposite sides of the pair of first magnets 202. The pair of first magnets 202 includes two magnets 203 or magnet sets each having one or more sub-magnets. In other words, unlike the example shown in FIGS. 1A and B, the first magnet consists of two magnets instead of one magnet.

FIG. 2B shows a magnet assembly 220 within the cylindrical sputter cathode 110 having three magnets, namely a first magnet 222 and a pair of second magnets. According to some embodiments, the first magnet 222 and each magnet of the pair of second magnets can have substantially the same length. The pair of second magnets has a first magnet unit 226 and a second magnet unit 228 provided on opposite sides of the first magnet 222. The magnet assembly 220 includes one or more (e.g., shaped or un-shaped) pole pieces. According to some embodiments, which can be combined with other embodiments described herein, the one or more pole pieces can be made of a material having a high permeability.

In some implementations, one or more first pole pieces 230 can be provided at the first magnet 222. As an example, one or more first pole pieces 230, such as two first pole pieces, can be provided at each of the pole ends of the first magnet 222. In particular, the one or more first pole pieces 230 can be provided at the positions between an inner surface of the cylindrical sputter cathode 110 and each of the poles or pole ends of the first magnet 222. According to some embodiments, the one or more first pole pieces 230 can be shaped pole pieces. As an example, an area of the one or more first pole pieces 230 facing the inner surface of the cylindrical sputter cathode 110 can have a shape that substantially corresponds to the shape of the inner surface of the cylindrical sputter cathode 110.

One or more second pole pieces 232 can be provided at the pair of second magnets. As an example, one or more second pole pieces 232, such as one pole piece, can be provided at each pole end of each of the second magnets, such as the first magnet unit 226 and the second magnet unit 228. In particular, the one or more second pole pieces 232 can be provided at the positions between the inner surface of the cylindrical sputter cathode 110 and each of the poles or pole ends of the second magnets. In some implementations, the one or more second pole pieces 232 can be shaped pole pieces. As an example, an area of the one or more second pole pieces 232 facing the inner surface of the cylindrical sputter cathode 110 can have a shape that substantially corresponds to the shape of the inner surface of the cylindrical sputter cathode 110.

Referring to FIG. 2C, according to a further aspect of the present disclosure, an apparatus configured for sputter deposition on a substrate is provided. The apparatus includes a cylindrical sputter cathode 110 rotatable around a rotational axis, and a magnet assembly 240 within the cylindrical sputter cathode 110 and configured to provide a first plasma racetrack and a second plasma racetrack on opposite sides of the cylindrical sputter cathode 110. The magnet assembly 240 includes, or consists of, two magnets 242 each having two poles and one or more sub-magnets, wherein the two magnets 242 are configured for generating both the first plasma racetrack and the second plasma racetrack. The two poles of each magnet are shown on the left and the right side, respectively, of the dashed line in FIG. 2C.

In some implementations, the magnet assembly 240 includes one or more pole pieces. In some implementations, one or more first pole pieces 244, such as one first pole piece, can be provided at a side of each of the two magnets 242 facing the inner surface of the cylindrical sputter cathode 110. In particular, the one or more first pole pieces 244 can be provided at the positions between the inner surface of the cylindrical sputter cathode 110 and each magnet of the two magnets 242. According to some embodiments, the one or more first pole pieces 244 can be shaped pole pieces.

One or more second pole pieces 246 can be provided between the two magnets 242. As an example, two second pole pieces can be provided between the two magnets 242. The two second pole pieces can be spaced apart from each other such that a gap is provided between the two second pole pieces.

FIG. 3A shows a cross-sectional side view of the apparatus 100 of FIG. 1A. The cylindrical sputter cathode 110 is rotatable around the rotational axis 1. The rotational axis 1 can be a cylinder axis of the cylindrical sputter cathode 110. In the center plane 3 perpendicular to the rotational axis 1, the magnet assembly has three magnets, i.e., the first magnet 122 and the pair of second magnets. The first magnet 122 and the pair of second magnets can be symmetrical with respect to the rotational axis 1 of the cylindrical sputter cathode 110. In some implementations, the rotational axis 1 of the cylindrical sputter cathode 110 is a substantially vertical rotational axis. “Substantially vertical” is understood particularly when referring to the orientation of the rotational axis 1, to allow for a deviation from the vertical direction or orientation of ±20° or below, e.g. of ±10° or below. Yet, the axis orientation is considered substantially vertical, which is considered different from the horizontal orientation.

According to some embodiments, which can be combined with other embodiments described herein, the first magnet 122 is centered in the cylindrical sputter cathode 110. As an example, the first magnet 122 can be positioned centered in the cylindrical sputter cathode 110, and the second magnets, such as the first magnet unit 124 and the second magnet unit 126, can be provided off-centered in the cylindrical sputter cathode 110.

FIG. 3B shows a schematic side view of the apparatus 100 configured for sputter deposition on a substrate having a plasma racetrack on a side thereof. FIG. 3B exemplarily shows the first plasma racetrack 130 on a side of the cylindrical sputter cathode 110.

The plasma racetrack forms one single plasma zone. The two vertical portions of the plasma racetrack are connected by horizontal portions of minimal length at the end of the plasma racetrack to form a single contiguous plasma zone or a single plasma racetrack. The plasma racetrack forms a loop or torus extending over the target surface. An advantage of minimizing the racetrack length in the horizontal direction is because there can be excessive target erosion there, leading to thicker deposition at the top and bottom areas of the substrate as well as a shortened target life.

According to some embodiments, which can be combined with other embodiments described herein, the first plasma racetrack and the second plasma racetrack are connected to form one single plasma racetrack, particularly during a sputter deposition process. As an example, the first plasma racetrack and the second plasma racetrack each have the shape shown in FIG. 3B, wherein the loops or tori are connected at some point in order to provide for the single plasma racetrack. Connecting the first plasma racetrack and the second plasma racetrack can further improve a symmetry of the first plasma racetrack and the second plasma racetrack.

FIG. 3C shows a cross-sectional side view of an apparatus 100′ configured for sputter deposition on a substrate according to further embodiments described herein. The apparatus 100′ of FIG. 3C is similar to the apparatus described with respect to FIG. 3A, and a description of similar or identical aspects is not repeated.

According to some embodiments, which can be combined with other embodiments described herein, the apparatus 100′ includes one or more magnet connection devices. The one or more magnet connection devices are configured to connect end portions of two magnets of the two, three or four magnets of the magnet assembly. As an example, the one or more magnet connection devices are configured to connect end portions of the pair of second magnets. Particularly, one or more first magnet connection device 128 can be configured to connect or bridge first end portions, e.g., top portions of the first magnet unit 124 and the second magnet unit 126. One or more second magnet connection devices 129 can be configured to connect or bridge second end portions, e.g., bottom portions of the first magnet unit 124 and the second magnet unit 126. The one or more magnet connection devices are configured to influence and/or shape the magnetic field provided by the magnet assembly, for example, to provide the curved end portions of the first racetrack and the second racetrack, respectively, as illustrated in FIG. 3B.

In some implementations, the one or more magnet connection devices and the two magnets connected by the one or more magnet connection devices can be integrally formed. Specifically, the one or more magnet connection devices and the two magnets can be made of a single piece of material. In further implementations, the one or more magnet connection devices can be separate pole pieces made of, for example, iron.

According to some embodiments, the one or more magnet connection devices can have a curved shape. However, the present disclosure is not limited thereto and the one or more magnet connection devices can have other shapes suitable to connect the two magnets, such as the end portions of the first magnet unit 124 and the second magnet unit 126.

FIG. 3D shows a cross-sectional side view of a section of an apparatus configured for sputter deposition on a substrate according to yet further embodiments described herein. The apparatus is similar to the apparatus shown in FIG. 3C, the difference lying in the configuration of the one or more magnet connection devices. Further, the magnets of the apparatus of FIG. 3D can have a pole configuration similar to the pole configuration of the magnets of the apparatus described with respect to FIGS. 2A and/or B, and a description of similar or identical aspects is not repeated.

According to some embodiments, which can be combined with other embodiments described herein, at least one magnet connection device of the one or more magnet connection devices includes two or more magnet connection units 328. The two or more magnet connection units 328 can be arranged to connect or bridge end portions of the first magnet unit 124 and the second magnet unit 126. Although the upper magnet connection device is shown in FIG. 3D, a lower connection device having two or more magnet connection units can be provided. In the apparatus of FIG. 3D, racetrack ends can be formed using a polarization direction into and out of the plane of the drawing sheet.

FIG. 3E shows a cross-sectional side view of an apparatus 100″ configured for sputter deposition on a substrate according to further embodiments described herein. In the apparatus 100″ of FIG. 3E, racetrack ends can be formed using facing/opposing magnets where a polarization direction is in the plane of the drawing sheet. The magnets of the apparatus 100″ of FIG. 3E can have a pole configuration similar to the pole configuration of the magnets of the apparatus described with respect to FIG. 2C, and a description of similar or identical aspects is not repeated.

According to some embodiments, which can be combined with other embodiments described herein, the apparatus 100″ includes a first magnet 122″, a second magnet 124″, and one or more magnet connection devices. The first magnet 122″ and the second magnet 124″ can be arranged substantially symmetrically with respect to the rotational axis 1. In particular, the first magnet 122″ and the second magnet 124″ can be positioned off-centered within the cylindrical sputter cathode 110.

The one or more magnet connection devices are configured to connect end portions of the first magnet 122″ and the second magnet 124″. As an example, one or more first magnet connection device 128″ can be configured to connect or bridge first end portions, e.g., top portions of the first magnet 122″ and the second magnet 124″. One or more second magnet connection devices 129″ can be configured to connect or bridge second end portions, e.g., bottom portions of the first magnet 122″ and the second magnet 124″.

The first magnet 122″ has a first pole and a second pole. As shown in FIG. 3E, the first pole (e.g., the north pole) of the first magnet 122″ can be on the left side of the dashed line, and the second pole (e.g., the south pole) of the first magnet 122″ can be on the right side of the dashed line. Likewise, the second magnet 124″ has a first pole and a second pole. As shown in FIG. 3E, the first pole (e.g., the north pole) of the second magnet 124″ can be on the right side of the dashed line, and the second pole (e.g., the south pole) of the second magnet 124″ can be on the left side of the dashed line.

In some implementations, the one or more magnet connection devices and the two magnets connected by the one or more magnet connection devices can be integrally formed. Specifically, the one or more magnet connection devices, the first magnet 122″ and the second magnet 124″ can be made of a single piece of material. In further implementations, the one or more magnet connection devices can be separate units including a magnetic material (e.g., the material of the first magnet 122″ and the second magnet 124″) and/or a high permeability material, for example, iron.

According to some embodiments, the one or more magnet connection devices can have a curved shape. However, the present disclosure is not limited thereto and the one or more magnet connection devices can have other shapes suitable to connect the two magnets, such as the end portions of the first magnet 122″ and the second magnet 124″.

In some implementations, the apparatus 100″ includes one or more pole pieces, such as one or more first pole pieces 127″ (e.g., one or more outer pole pieces) and/or one or more second pole pieces 125″ (e.g., one or more inner pole pieces). The one or more pole pieces can be configured similarly or identically to the pole pieces illustrated in FIG. 2C. The one or more second pole pieces 125″ can be positioned between the first magnet 122″ and the second magnet 124″. The one or more first pole pieces 127″ can be positioned between the first magnet 122″ and/or the second magnet 124″ and the cylindrical sputter cathode 110. As an example, the one or more first pole pieces 127″ can at least partially enclose at least one of the first magnet 122″ (e.g., an outer surface of the first magnet 122″), the second magnet 124″ (e.g., an outer surface of the second magnet 124″), and the one or more pole pieces (e.g., an outer surface of the one or more pole pieces).

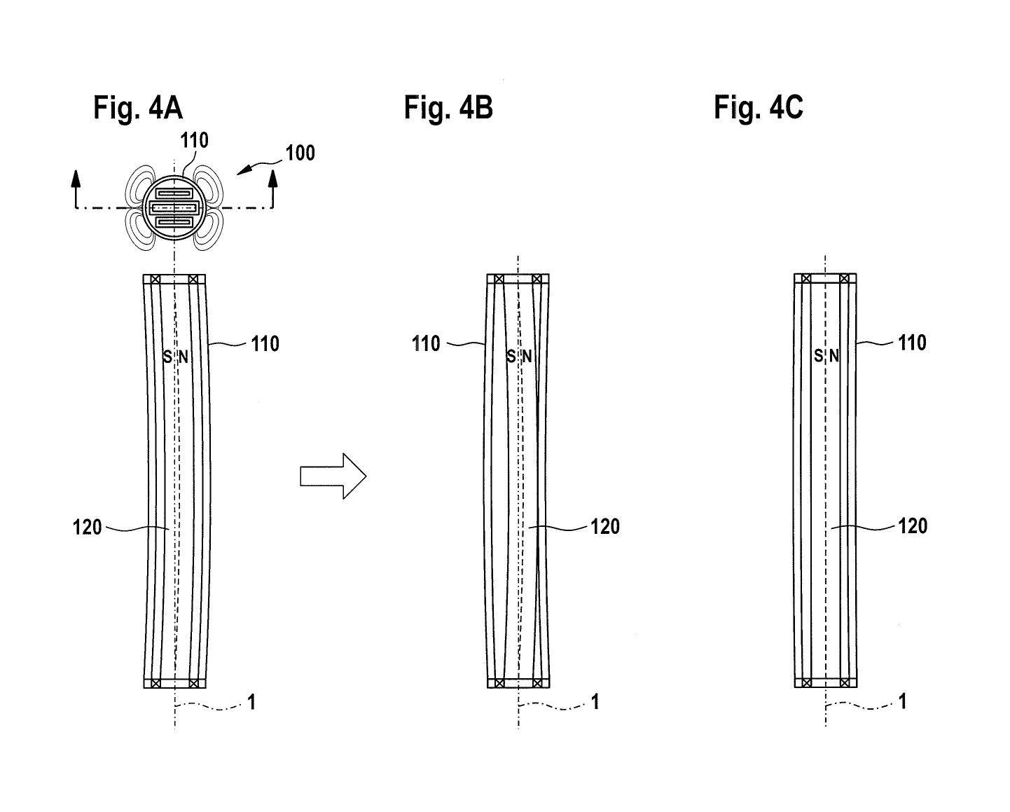

FIGS. 4A-C show schematic side cross-sectional views of the apparatus 100 configured for sputter deposition on a substrate.

With respect to the cylindrical sputter cathode 110 and/or target, a straightness error in the cylindrical sputter cathode 110 and/or target is averaged side to side as the cylindrical sputter cathode 110 rotates (see FIG. 4B: the cylindrical sputter cathode 110 is rotated by 180° compared to FIG. 4A). However, the magnet assembly 120 straightness error is not averaged, since the magnet assembly 120 is stationary, specifically while the cylindrical sputter cathode 110 is rotating around the magnet assembly 120. In particular, the magnet assembly 120 is fixed so a difference in a gap between a magnet surface and the target surface at the ends and at the center is most exaggerated. End gaps are equal—controlled by the bearings. In other words, straightness errors in the magnet assembly 120 and the cylindrical sputter cathode 110 and/or target create a gap difference from the center to the ends of the cylindrical sputter cathode 110 and/or target.

A bending of a sputter deposition source can particularly occur in single-directional sputter deposition sources. Specifically, bending can occur due to a temperature gradient in the sputter deposition source. As an example, in single-directional sputter deposition sources, the plasma racetrack is only on one side of the sputter deposition source. The plasma heats the sputter deposition source asymmetrically side to side. This leads to a non-uniform temperature distribution in the sputter deposition source, leading in turn to differential thermal expansion and a formation/bending of the sputter deposition source can occur. Regarding sputter deposition sources having more than one independent magnetron, it is challenging to make the two magnetic fields on the opposing sides of the sputter deposition source to have exactly the same strength. This could also lead to a non-uniform temperature distribution in the sputter deposition source and a bending of the sputter deposition source.

The above disadvantages related to the bending of the magnet assembly can be overcome by the present disclosure. One single combined magnetron is provided in the bi-directional sputter deposition source to generate magnetic fields on each side of the target surface. Specifically, the same individual magnets create the same field on each side of the target surface. A bending of the sputter deposition source can be reduced or even avoided, as illustrated in FIG. 4C. A target straightness error can be averaged side to side as described above.

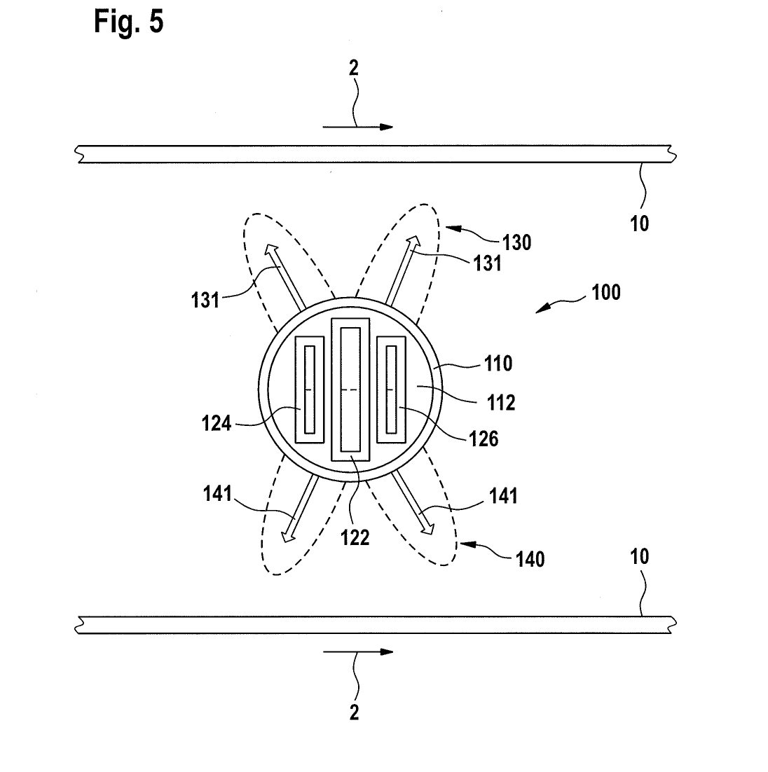

FIG. 5 shows a schematic top view of an apparatus 100, which is a bi-directional sputter deposition source, used for a simultaneous processing of two substrates according to embodiments described herein.

FIG. 5 shows two substrates provided on opposite sides of the apparatus 100. In particular, the apparatus 100 is provided between the two substrates 10. According to some embodiments, the substrates 10 are moved in a transport direction 2 past the apparatus 100 during a sputter deposition process. As an example, both substrates can be moved in the same transport direction. In other examples, the substrates can be moved in opposite transport directions. The transport directions of the two substrates 10 can be substantially parallel to each other.

The two substrates 10 are coated with material from the target of the apparatus 100 originating from the first plasma racetrack 130 and the second plasma racetrack 140. In particular, one or more substrates can be moved past a first side of the apparatus 100 to be coated by material originating from the first plasma racetrack 130. One or more substrates can be moved past a second side opposite the first side of the apparatus 100 to be coated by material originating from the second plasma racetrack 140. The first side and the second side are the opposite sides of the apparatus 100.

In some embodiments, the magnet assembly 120 is stationary or non-movable in the cylindrical sputter cathode 110, specifically during a sputter deposition process. According to some embodiments, which can be combined with other embodiments herein, the magnet assembly 120 is configured to provide at least one of the first plasma racetrack 130 and the second plasma racetrack 140 non-perpendicular with respect to a substrate surface on which material is to be deposited. The magnet assembly 120, and specifically the first magnet 122 and the pair of second magnets can be tilted with respect to the substrate surface. Specifically, a symmetry line of the magnet assembly 120 can be non-perpendicular to the substrate surface. A sputtering direction is angled with respect to the substrate 10 to prevent or reduce a deposition on, for example, a leading or tailing edge of the substrate.

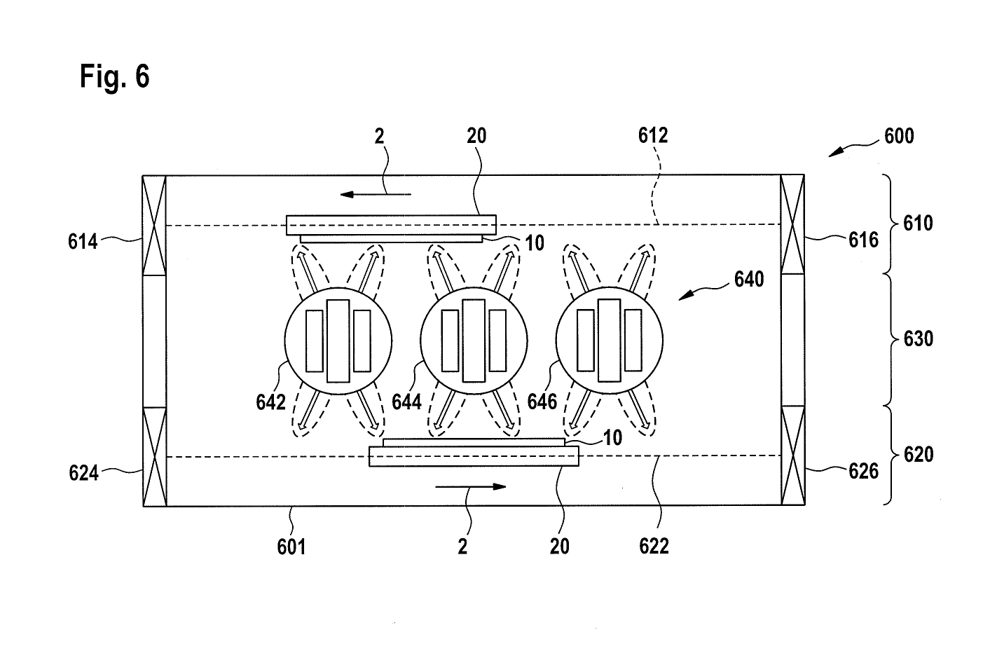

FIG. 6 shows a schematic view of a system 600 configured for sputter deposition on a substrate according to embodiments described herein. The system 600 includes a vacuum chamber 601 and one or more apparatuses 640, e.g., the bi-directional sputter deposition sources, according to the embodiments described herein in the vacuum chamber 601. The system 600 can be configured for simultaneous sputter deposition on two or more substrates.

According to some embodiments, one single vacuum chamber, such as the vacuum chamber 601, for deposition of layers therein can be provided. A configuration with one single vacuum chamber can be beneficial in an in-line processing apparatus, for example, for dynamic deposition. The one single vacuum chamber, optionally with different areas, does not include devices for vacuum tight sealing of one area of the vacuum chamber with respect to another area of the vacuum chamber. In other implementations, further chambers can be provided adjacent to the vacuum chamber 601. The vacuum chamber 601 can be separated from adjacent chambers by a valve, which may have a valve housing and a valve unit.

In some embodiments, an atmosphere in the vacuum chamber 601 can be individually controlled by generating a technical vacuum, for example with vacuum pumps connected to the vacuum chamber 601, and/or by inserting process gases in the deposition area(s) in the vacuum chamber 601. According to some embodiments, process gases can include inert gases such as argon and/or reactive gases such as oxygen, nitrogen, hydrogen and ammonia (NH3), Ozone (O3), or the like.

According to some embodiments, which can be combined with other embodiments described herein, the vacuum chamber 601 includes a first deposition region 610 and a second deposition region 620, wherein the one or more apparatuses 640 are provided between the first deposition region 610 and the second deposition region 620. As an example, the one or more apparatuses 640 can be provided in an intermediate region 630 between the first deposition region 610 and the second deposition region 620. The first deposition region 610 can be provided at a first side of the one or more apparatuses 640 and the second deposition region 620 can be provided at a second side of the one or more apparatuses 640 opposite the first side.

In some implementations, the vacuum chamber 601 can include one or more load locks, such as a first load lock 614 and a second load lock 616 configured for access to the first deposition region 610 and a third load lock 624 and a fourth load lock 626 configured for access to the second deposition region 620. Substrates can be moved into and out of the vacuum chamber 601 and optionally the respective deposition regions using the one or more load locks.

The one or more apparatuses 640 can include a first sputter deposition source 642, a second sputter deposition source 644, and a third sputter deposition source 646. However, the present disclosure is not limited thereto, and any suitable number of apparatuses can be provided, for example, less than three or more than three apparatuses. In some implementations, the one or more apparatuses 640 can be connected to an AC power supply (not shown) such that the one or more apparatuses 640 can be powered in an alternating paired manner. However, the present disclosure is not limited thereto and the one or more apparatuses 640 can be configured for DC sputtering or a combination of AC and DC sputtering.

In some implementations, the system 600 includes one or more substrate transportation paths extending through the vacuum chamber 601. As an example, a first substrate transportation path 612 can extend through the first deposition region 610 and a second substrate transportation path 622 can extend through the second deposition region 620. The first substrate transportation path 612 and the second substrate transportation path 622 can extend substantially parallel to each other.

The substrates 10 can be positioned on respective carriers. The carriers 20 can be configured for transportation along the one or more substrate transportation paths or transportation tracks extending in the transport direction 2. Each carrier is configured to support a substrate, for example, during a vacuum deposition process or layer deposition process, such as a sputtering process or a dynamic sputtering process. The carrier 20 can include a plate or a frame configured for supporting the substrate 10, for example, using a support surface provided by the plate or frame. Optionally, the carrier 20 can include one or more holding devices (not shown) configured for holding the substrate 10 at the plate or frame. The one or more holding devices can include at least one of mechanical, electrostatic, electrodynamic (van der Waals), electromagnetic and/or magnetic devices, such as mechanical and/or magnetic clamps.

In some implementations, the carrier 20 includes, or is, an electrostatic chuck (E-chuck). The E-chuck can have a supporting surface for supporting the substrate 10 thereon. In one embodiment, the E-chuck includes a dielectric body having electrodes embedded therein. The dielectric body can be fabricated from a dielectric material, preferably a high thermal conductivity dielectric material such as pyrolytic boron nitride, aluminum nitride, silicon nitride, alumina or an equivalent material. The electrodes may be coupled to a power source, which provides power to the electrode to control a chucking force. The chucking force is an electrostatic force acting on the substrate 10 to fix the substrate 10 on the supporting surface.

In some implementations, the carrier 20 includes, or is, an electrodynamic chuck or Gecko chuck (G-chuck). The G-chuck can have a supporting surface for supporting the substrate thereon. The chucking force is an electrodynamic force acting on the substrate to fix the substrate 10 on the supporting surface.

According to some embodiments, which can be combined with other embodiments described herein, the carrier 20 is configured for supporting the substrate 10 in a substantially vertical orientation, in particular during the sputter deposition process. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable carrier and/or substrate position. Further, fewer particles reach the substrate surface when the substrate is tilted forward. Yet, the substrate orientation, e.g., during the sputter deposition process, is considered substantially vertical, which is considered different from the horizontal substrate orientation, which may be considered as horizontal ±20° or below.

According to some embodiments, which can be combined with other embodiments described herein, the system 600 is configured for dynamic sputter deposition on the substrate(s). A dynamic sputter deposition process can be understood as a sputter deposition process in which the substrate 10 is moved through the deposition region(s) along the transport direction 2 while the sputter deposition process is conducted. In other words, the substrate 10 is not stationary during the sputter deposition process.

In some implementations, the system 600 is an in-line processing system, e.g., a system for dynamic sputtering, particularly for dynamic vertical sputtering. The in-line processing system can provide for a uniform processing of the substrate 10, for example, a large area substrate such as a rectangular glass plate. The processing tools, such as the one or more bi-directional sputter deposition sources, extend mainly in one direction (e.g., the vertical direction) and the substrate 10 is moved in a second, different direction (e.g., the transport direction which can be the horizontal direction).

Apparatuses or systems for dynamic sputter deposition, such as in-line processing apparatuses or systems, have the advantage that processing uniformity, for example, layer uniformity, in one direction is only limited by the ability to move the substrate 10 at a constant speed and to keep the one or more sputter deposition sources stable. The deposition process of an in-line processing system is determined by the movement of the substrate 10 past the one or more sputter deposition sources. For an in-line processing system, the deposition region or deposition area can be an essentially linear area for processing, for example, a large area rectangular substrate. The deposition region can be a region or an area into which deposition material is ejected from the one or more sputter deposition sources for being deposited on the substrate 10. In contrast thereto, for a stationary processing apparatus, the deposition region or deposition area would basically correspond to at least the whole area of the substrate 10.

In some implementations, a further difference of an in-line processing system, for example, for dynamic deposition, as compared to a stationary processing apparatus can be formulated by the fact that the dynamic processing system can have one single vacuum chamber, optionally with different areas such as the first deposition region 610 and the second deposition region 620, wherein the vacuum chamber 601 does not include devices for vacuum tight sealing of one area of the vacuum chamber with respect to another area of the vacuum chamber.

According to some embodiments, the system 600 includes a magnetic levitation system for holding the carrier 20 in a suspended state. Optionally, the system 600 can use a magnetic drive system configured for moving or conveying the carrier 20 in the transport direction 2. The magnetic drive system can be integrated together with the magnetic levitation system or can be provided as a separate entity.

The embodiments described herein can be utilized for evaporation on large area substrates, e.g., for display manufacturing. Specifically, the substrates or carriers, for which the structures and methods according to embodiments described herein are provided, are large area substrates. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall particularly embrace rigid or inflexible substrates, e.g., glass plates and metal plates. However, the present disclosure is not limited thereto and the term “substrate” can also embrace flexible substrates such as a web or a foil. According to some embodiments, the substrate 10 can be made of any material suitable for material deposition. For instance, the substrate 10 can be made of a material selected from the group consisting of glass (for instance soda-lime glass, borosilicate glass, and the like), metal, polymer, ceramic, compound materials, carbon fiber materials, mica or any other material or combination of materials which can be coated by a deposition process.

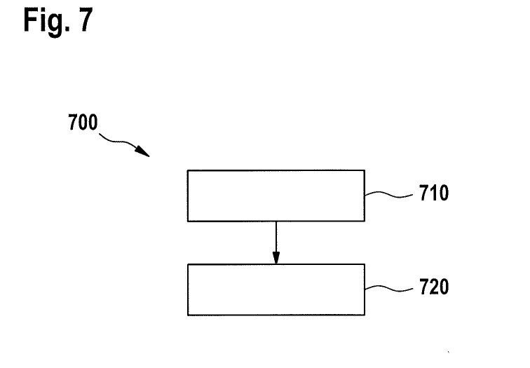

FIG. 7 shows a flow chart of a method 700 for sputter deposition on a substrate according to embodiments described herein. The method 700 can utilize the systems and apparatuses, such as the bi-directional sputter deposition sources, according to the embodiments described herein.

The method 700 includes in block 710 a generating of a first plasma racetrack and a second plasma racetrack, e.g., on opposite sides of a cylindrical sputter cathode, using a magnet assembly in the cylindrical sputter cathode having two, three or four magnets, such as a first magnet and a pair of second magnets, for generating both the first plasma racetrack and the second plasma racetrack. The method can further include a simultaneous coating of two or more substrates by material originating from the first plasma racetrack and the second plasma racetrack (block 720).

According to embodiments described herein, the method for sputter deposition on a substrate can be conducted using computer programs, software, computer software products and the interrelated controllers, which can have a CPU, a memory, a user interface, and input and output devices being in communication with the corresponding components of the systems and apparatuses according to the embodiments described herein.

The present disclosure provides a cylindrical sputter cathode having one single integrated magnetron having two, three or four magnets configured to generate magnetic fields on two opposing sides of a target surface. Specifically, the same individual magnets create the same field on the opposing sides of the target surface. This overcomes the disadvantages of having two independent plasma racetracks on the same target surface provided by two independent magnetrons. Specifically, it is challenging to make the two fields have exactly the same strength. The stronger field will have a higher sputter rate, causing thickness non-uniformity. The embodiments of the present disclosure can provide for substantially the same sputter rate on both sides of the cylindrical sputter cathode.

Further, the integrated magnet assembly for both sides can prevent a bending of the magnet assembly due to a side-to-side temperature difference in the sputter deposition source. A thickness uniformity of the layers deposited on the substrates can be improved. The bi-directional sputter deposition source can be used to simultaneously coat two substrates provided at opposing sides of the sputter deposition source. A throughput of a processing system, such as a sputter deposition system, can be increased. Moreover, the bi-directional sputter deposition source uses less installation space within the vacuum chamber and the factory when compared to, for example, two separate sputter deposition sources used to simultaneously process two substrates.

While the foregoing is directed to embodiments of the disclosure, other and further embodiments of the disclosure may be devised without departing from the basic scope thereof, and the scope thereof is determined by the claims that follow.

1. An apparatus configured for sputter deposition on a substrate, comprising:
a cylindrical sputter cathode rotatable around a rotational axis; and
a magnet assembly within the cylindrical sputter cathode and configured to provide a first plasma racetrack and a second plasma racetrack, wherein the magnet assembly includes two, three or four magnets each having two poles and one or more sub-magnets, wherein the two, three or four magnets are configured for generating both the first plasma racetrack and the second plasma racetrack.

2. The apparatus of claim 1, wherein the two, three or four magnets are three magnets including a first magnet having one or more first sub-magnets and a pair of second magnets each having one or more second sub-magnets, and wherein the first magnet and the pair of second magnets are configured for generating both the first plasma racetrack and the second plasma racetrack.

3. The apparatus of claim 1, wherein the magnet assembly is stationary in the cylindrical sputter cathode.

4. The apparatus of claim 2, wherein the first magnet is centered in the cylindrical sputter cathode.

5. The apparatus of claim 2, wherein the first magnet and the pair of second magnets are symmetrical with respect to the rotational axis of the cylindrical sputter cathode.

6. The apparatus of claim 1, wherein the magnet assembly is configured to provide the first plasma racetrack and the second plasma racetrack symmetrical with respect to the rotational axis.

7. The apparatus of claim 1, wherein, during a sputter deposition process, the first plasma racetrack and the second plasma racetrack are connected to form one single plasma racetrack.

8. The apparatus of claim 2, wherein each second magnet of the pair of second magnets includes a first magnetic pole and a second magnetic pole opposite the first magnetic pole, wherein the first magnetic poles of the pair of second magnets are oriented towards the first plasma racetrack and the second magnetic poles of the pair of second magnets are oriented towards the second plasma racetrack.

9. The apparatus of claim 2, wherein the first magnet includes a first magnetic pole and a second magnetic pole opposite the first magnetic pole, wherein the first magnetic pole of the first magnet is oriented towards the second plasma racetrack and the second magnetic pole of the first magnet is oriented towards the first plasma racetrack.

10. The apparatus of claim 8, wherein the first magnetic pole is a magnetic south pole and the second magnetic pole is a magnetic north pole, or the first magnetic pole is a magnetic north pole and the second magnetic pole is a magnetic south pole.

11. The apparatus of claim 1, wherein the rotational axis of the cylindrical sputter cathode is a vertical rotational axis.

12. The apparatus of claim 1, wherein the magnet assembly is configured to provide at least one of the first plasma racetrack and the second plasma racetrack non-perpendicular with respect to a substrate surface on which material is to be deposited.

13. The apparatus of claim 1, further including one or more magnet connection devices configured to connect end portions of two magnets of the two, three or four magnets of the magnet assembly.

14. System configured for sputter deposition on a substrate, comprising:
a vacuum chamber; and
one or more apparatuses; the apparatuses comprising:
a cylindrical sputter cathode rotatable around a rotational axis; and
a magnet assembly within the cylindrical sputter cathode and configured to provide a first plasma racetrack and a second plasma racetrack wherein the magnet assembly includes two, three or four magnets each having two poles and one or more sub-magnets, wherein the two, three or four magnets are configured for generating both the first plasma racetrack and the second plasma racetrack in the vacuum chamber.

15. The system of claim 14, wherein the vacuum chamber includes a first deposition region and a second deposition region, wherein the one or more apparatuses are provided between the first deposition region and the second deposition region.

16. The system of claim 14, wherein the system is an in-line processing system configured for dynamic sputter deposition on the substrate.

17. Method for sputter deposition on a substrate, comprising:
generating a first plasma racetrack and a second plasma racetrack using a magnet assembly in a cylindrical sputter cathode including two, three or four magnets, wherein the two, three or four magnets are configured for generating both the first plasma racetrack and the second plasma racetrack.

18. The apparatus of claim 2, wherein the magnet assembly is stationary in the cylindrical sputter cathode.

19. The apparatus of claim 3, wherein the first magnet is centered in the cylindrical sputter cathode.

20. The apparatus of claim 11, wherein the first magnetic pole is a magnetic south pole and the second magnetic pole is a magnetic north pole, or the first magnetic pole is a magnetic north pole and the second magnetic pole is a magnetic south pole.
